(19) United States
(12) Patent Application Publication
(10) Pub. No.: US 2014/0151854 A1
(43) Pub. Date: Jun. 5, 2014

(54) Method for Separating a Layer and a Chip Formed on a Layer

(71) Applicant: INFINEON TECHNOLOGIES AG, Neubiberg (DE)

(72) Inventors: Manfred Engelhardt, Villach-Landskron (AT); Frank Hoffmann, Freiberg (DE)

(73) Assignee: Infineon Technologies AG, Neubiberg (DE)

(21) Appl. No.: 13/691,475

(22) Filed: Nov. 30, 2012

(51) Int. Cl. H01L 21/02; H01L 29/06

(52) U.S. Cl. CPC H01L 21/0203; H01L 29/06
USPC 257/618; 438/690

(57) ABSTRACT

A method for separating a layer from a substrate. The method includes providing a plurality of trenches extending from a first main surface of the substrate into the substrate. A heat treatment of the substrate is performed such that edges of the trenches grow together at the first main surface to form a closed layer at the first main surface, wherein lower portions of the trenches form one or more cavities within the substrate. After that the closed layer is separated from the substrate along the one or more cavities.

### TECHNICAL FIELD

Embodiments of the present invention refer to a method for separating one or more layers from a substrate and to a chip formed on a layer.

### BACKGROUND

In the context of this invention, a layer is understood to be a thin substrate which is produced based on a regular substrate (having a regular thickness), e.g., a Si or bulk SiC wafer. Today, bulk SiC wafers are processed until the end of the front end process flow. Here, subsequent SiC wafer thinning is done by mechanical grinding down to a layer thickness significantly below the thickness of the bulk SiC substrate (wafer), because often very thin layers are required due to electrical reasons. Such thin layers may have a layer thickness which is only a fraction of the thickness of the bulk SiC substrate (starting product). The grinding process (CMP process) is expensive due to the mechanical material properties of SiC. Furthermore, SiC bulk substrates are also very expensive. Thus, taking into consideration that only a thin layer of the bulk SiC substrate is required, a lot of material loss is generated due to the mechanical grinding. To sum up, producing electrical devices which are based on thin SiC layers is very expensive due to the expensive starting product, due to the high material loss and due to the expensive mechanical grinding process. Therefore, there is the need for an improved approach for such production processes.

### SUMMARY OF THE INVENTION

Embodiments of the invention provide a method for separating a layer from a substrate. The method comprises the steps of providing a plurality of trenches extending from a first main surface of the substrate into the substrate and performing a heat treatment of the substrate such that edges of the trenches grow together at the first main surface to form a closed layer at the first main surface, wherein lower portions of the trenches form one or more cavities within the substrate. After that the closed layer is separated from the substrate along the one or more cavities.

A further embodiment provides a method for separating layers from a substrate comprising silicon and/or carbon. The method comprises the following steps: providing a plurality of trenches extending from a first main surface of the substrate into the substrate, wherein the trenches are laterally and evenly distributed over an entire area of the substrate, wherein a diameter of each trench is larger than 350 nm and wherein an average pitch between two adjacent trenches is smaller than 10 μm. The following steps are providing hydrogen ambient surrounding the substrate and performing a heat treatment of the substrate at a temperature above 1000° C. such that edges of the trenches grow together at the first main surface to form a closed layer at the first main surface, wherein lower portions of the trenches form one or more cavities within the substrate. The step of performing the heat treatment is performed as long as the one or more cavities form an entire cavity extending in parallel to the first main surface of the substrate. The next step is separating the closed layer from the substrate along the one or more cavities. These steps of the method are repeated such that a plurality of closed layers is separated from the substrate.

A further embodiment provides a chip comprising a layer being thinner than 100 μm, a plurality of piles integrated into the layer and a chip area formed on the layer and comprising an integrated circuit.

### BRIEF DESCRIPTION OF THE DRAWINGS

Below, embodiments will subsequently be discussed referring to the enclosed drawings, wherein:

FIGS. 1a-1h show an exemplary flowchart of the steps for separating a layer from a substrate according to embodiments;

FIGS. 2a-2c is a show a further flow chart of optional steps for the method for separating a layer shown in FIG. 1;

FIGS. 3a and 3b show detailed representations of trenches for illustrating the step of providing a plurality of trenches of the method of FIG. 1;

FIGS. 4a and 4b show detailed representations of a cavity within a substrate for illustrating the step of performing a heat treatment of the method of FIG. 1;

FIG. 4c shows a detailed representation of a separated layer separated by an additional method step according to a further embodiment; and

FIG. 5 shows a schematic representation of a chip formed on a layer separated by a method according to embodiments.

### DETAILED DESCRIPTION OF ILLUSTRATIVE EMBODIMENTS

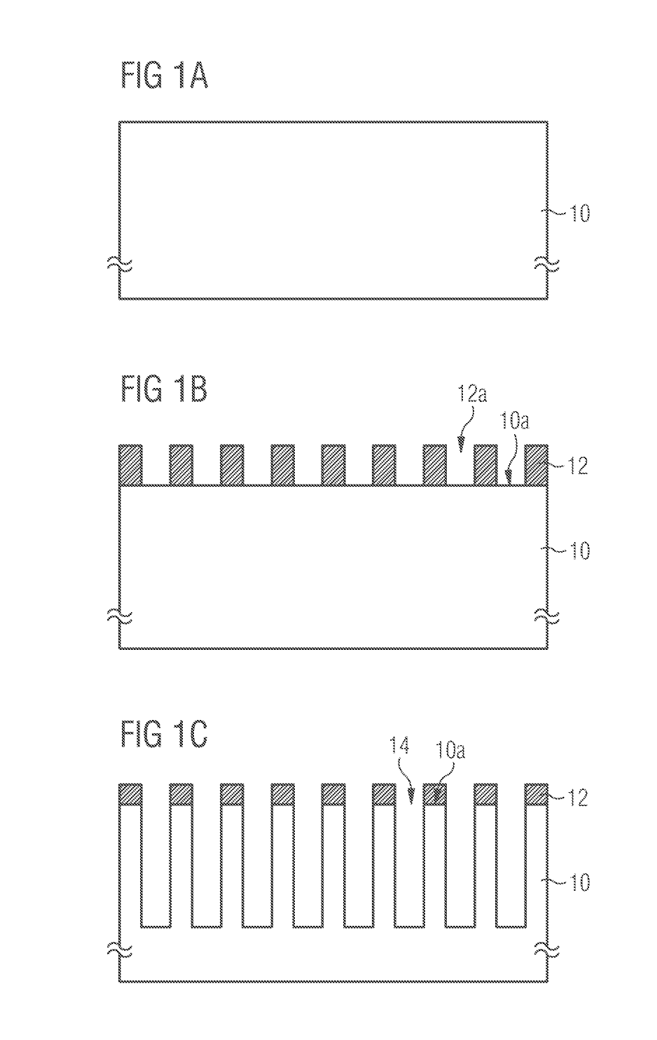

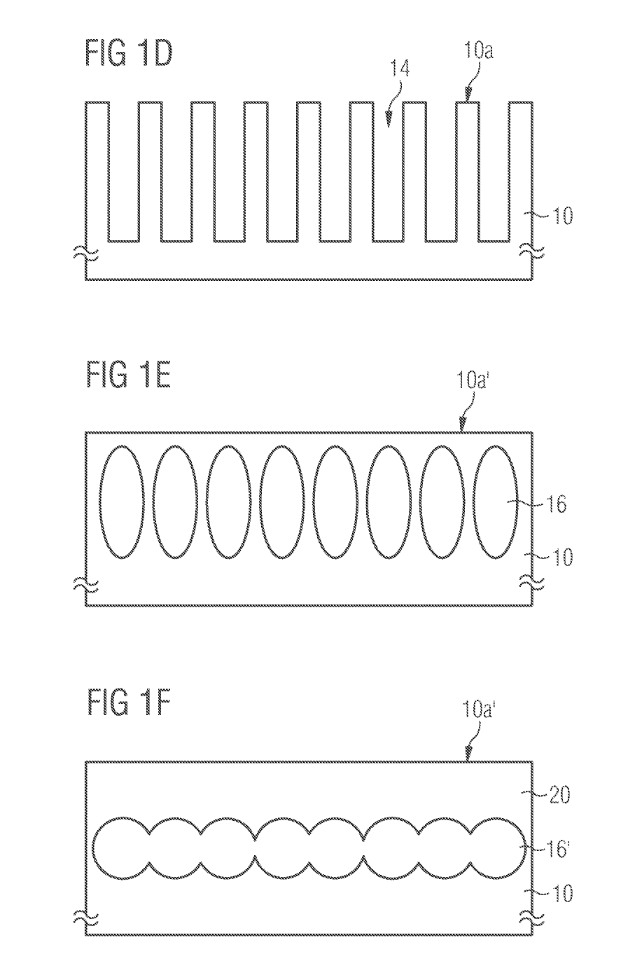

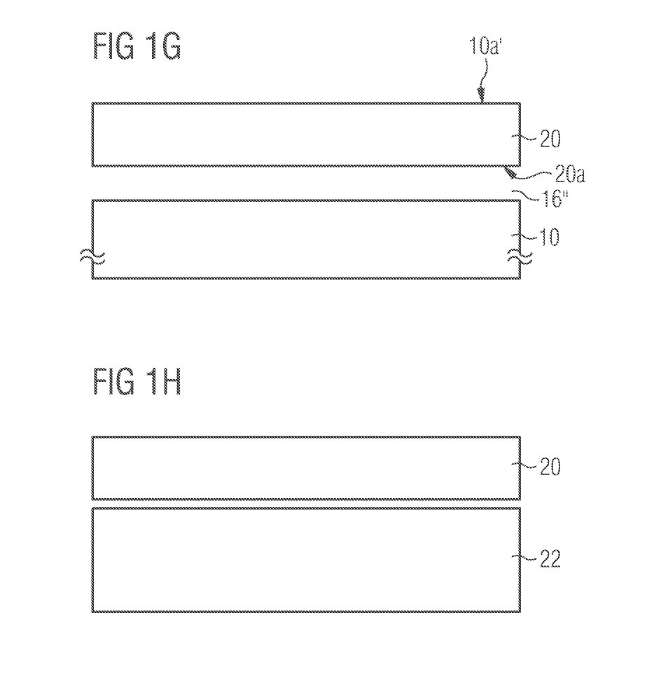

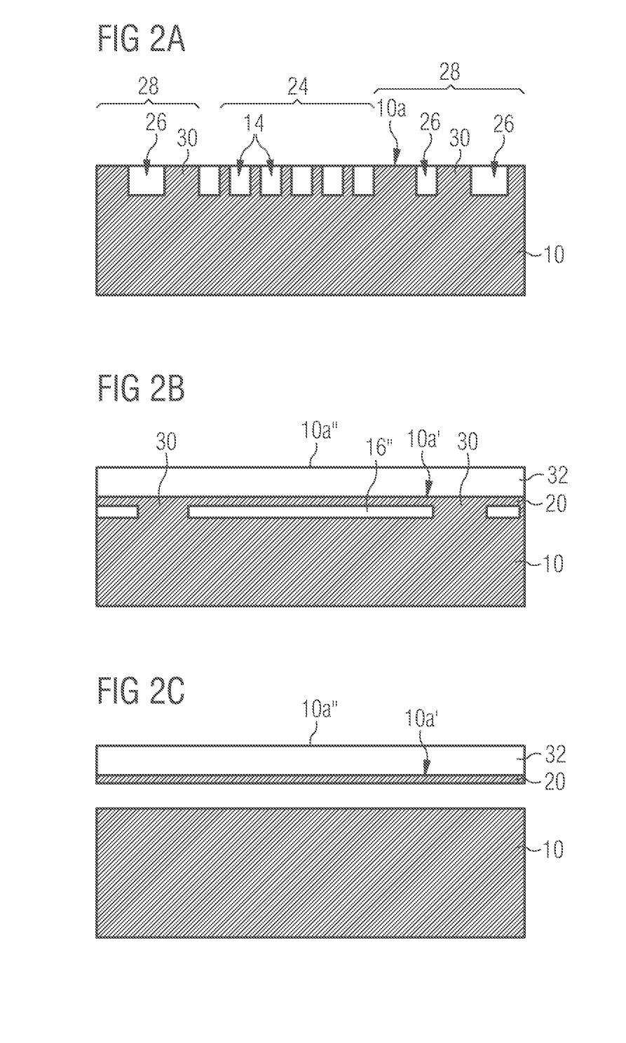

FIG. 1a shows a cross-sectional view of a substrate 10. The substrate 10 may be a bulk wafer comprising silicon (Si), carbon (C) or SiC. The substrate 10 represents the starting product having a thickness around 1000 μm, for example, from which the singular layer, e.g., a thin SiC layer (e.g., 20 μm), should be separated. It should be noted that the substrate 10 is thicker than illustrated, as indicated by the curly brackets.

FIG. 1b shows a first step of the method in which the substrate 10 is prepared for the first main step of providing a plurality of trenches. Here, a hardmask 12 comprising a pattern is provided to a first main surface 10a of the substrate 10. The provided hardmask 12, which may, for example, comprise a photoresist, is processed, e.g., by using lithography, such that a plurality of openings 12a are formed arranged with a substantially constant pitch. As illustrated, the plurality of openings 12a are arranged such that same are laterally distributed over an (entire) area of the main surface 10a which should be separated from the substrate 10. The pitch of the hardmask pattern 12 and a size of the openings 12a defines a pitch and a size of the plurality of trenches to be provided at the next step, because the hardmask 12 covers (protects) the substrate 10 in certain portions not to be etched.

FIG. 1c shows the substrate 10 after performing the step of etching. This step is done such that a plurality of trenches 14 aligned to the openings 12a of the hardmask pattern 12 is provided. The trenches 14, which are evenly distributed over the entire area of the substrate 10 or at least over the portion of same which should be separated, extend from the first main surface 10a into the substrate 10 (perpendicular to the main surface 10a). The providing of the tranches 14 may be performed by deep trench etching (RIE, Radiating Ion Etching) or by another etching technology which enables generating a high aspect ratio of the trenches 14. Although it is illustrated differently, the trenches 14 may extend into the substrate 10 up to a depth which is smaller than 25% or even smaller than 15% or 10% of the thickness of the substrate 10 (this holds at least for the first iteration of this method).

The pitch and the size of the trenches 14 is approximately equal to the pitch and the size of the openings 12a of the hardmask 12. The trenches 14 may, for example, have a diameter of 770 nm and an average pitch of 1 μm so that the spacing between two adjacent trenches 14 is around 230 nm. In general, the average pitch is smaller than 10 μm or preferably smaller than 5 μm or even smaller than 2 μm, wherein the diameter of the trenches 14 amounts to more than 300 nm or more than 500 nm, i.e., that the trenches 14 may have a diameter larger than 55% or 65% of the pitch. This leads to a high portion of the main surface 10a which comprises the trenches 14 when compared to a portion of the main surface 10a between the trenches 14.

FIG. 1d illustrates a possible post-processing step of the step of providing the trenches 14. Here, the hardmask pattern 12 is removed from the main surface 10a of the substrate 10, e.g., by using a solvent. After removing the hardcover an annealing process of the substrate 10 comprising the plurality of trenches 14 is performed as illustrated by FIGS. 1e to 1d.

FIG. 1e shows the substrate 10 after a heat treatment having a duration t₁, e.g., 20 seconds, 60 seconds or in general typically less than 300 seconds, at a temperature T₁, e.g., 850° C. or 1000° C. or above. This process comprising the annealing is called Venezia Process, which is typically performed in hydrogen ambient. This annealing results in a reflow of the substrate material so that the edges of the trenches 14 grow together at the first main surface 10a. At lower portions the trenches 14 are laterally enlarged so that each trench 14 forms a cavity 16 inside the substrate 10. The cavities 16 may have the shape of an ellipsis or in the 3D view of an ellipsoid which extends along a direction of the trench 14. It should be noted that the depth of the cavity 16 may be reduced when compared to the depth of the (previous) trench 14 because the annealing leads to a reflow of the substrate material to the upper and lower portions of the trenches 14.

FIG. 1f illustrates the following process step of the method in which the temperature treatment is continued at a second temperature T₂ (T₂ equal to or above the first temperature T₁). The process duration t₂ of this second part of the temperature treatment is typically increased when compared to the process duration t₁ (cf. FIG. 1e), i.e., t₂>t₁. Due to this second annealing process the shape of the cavities 16 is changed from the ellipsis-shape to a ball-shape (cf. shape-changed cavity 16′). Further, the edges of the trenches 14 have been closed at the first main surface 10a in order to form a closed main surface 10a′. As a consequence, a portion 20 of the substrate 10 between the closed main surface 10a′ and the plurality of shape-changed cavities 16′ is increased when compared to the same area of the substrate 10 in FIG. 1e. As illustrated, the plurality of cavities 16′ is laterally increased and thus grows partially together. This effect may be adjusted by adjusting the distance of two adjacent trenches 14 (cf. FIG. 1b).

FIG. 1g shows the third part of the annealing process in which the closed layer 20 is separated from the substrate 10 by connecting the plurality of cavities (cf. 16′) to a singular cavity 16″ extending along the layer 20. Consequently, the singular cavity 16″ is arranged between the substrate 10 and the closed layer 20. So, the cavity 16″ extends in parallel to the closed main surface 10a′ and, thus, along a second main surface 20a of the layer 20 formed by the cavity 16″ and facing the first main surface 10′. The separated thin layer 20 may have a thickness of 45 μm, 30 μm, 15 μm or below.

This separation process is done by preceding the high temperature treatment such that the plurality of cavities (cf. 16 or 16′) grow together and form the single cavity 16″. The duration t₃ of the third part of the annealing is longer than the duration t₁ and/or the duration t₂. To sum up, the annealing process shown in FIGS. 1e to 1g is performed until the plurality of cavities 16 have grown together to form the singular cavity 16″ separating the layer 20 and the substrate 20. Note that the separated thin layer 20 is separated from the substrate 20, but still arranged on same. Further, the thin layer 20 may be still connected to the substrate in an edge region (not shown) surrounding the portion of the layer 20 which should be separated.

FIG. 1h shows an optional step for handling the layer 20 during the front end process. Here, the layer 20 may be attached to a carrier 22, also referred to as handling substrate, which has the purpose of mechanically stabilizing the thin layer 20 and of improving the handling. The carrier 22 itself may consist of various materials. It may easily be a substrate wafer or a carrier with a so called pocket (cavity, recess material) or a carrier with support structures to hold the thin layer 20 during further (front end) processing. After the front end processing, the carrier may be removed.

According to a further embodiment the steps described by using FIGS. 1a to 1g (basic method steps) may be repeated for separated a further (thin) closed layer 20 from the same substrate 10. Thus, this enables the fabrication of a plurality of thin layers (thin SiC substrate) from the single substrate (single SiC bulk wafer). As a consequence of this, the total fabrication costs are reduced due to a reduced loss of material and due to avoiding mechanical grinding.

FIG. 2a shows a further variant of the step of providing the trenches 14 into the substrate 10 in a cross-sectional view. Here, the trenches 14 for forming the cavity are arranged in a first portion 24 of the closed main surface 10a, wherein further trenches 26 are arranged in a second portion 28 adjacent to or within the first portion 24. The distance between the further trench 26 and an adjacent trench 14 or 26 in the second portion 28 is enlarged when compared to the distance between two adjacent trenches 14 in the first portion 24. Due to the enlarged spacing one or more piles 30 are formed in the second portion 28. The piles 30 have the purpose of increasing the stability of the layer 20 to be separated.

FIG. 2b illustrates a cross-sectional view of the substrate 10 after performing the heat treatment. As illustrated by FIG. 2b, the piles 30 remain after the heat treatment. The piles 30 are arranged such that the cavity 16″, which is formed by a plurality of cavities (not shown) during the annealing process, lies between the piles 30 or such that the piles 30 are arranged within the layer 20. The piles 30 may have a size of 2×2 μm, wherein the distance between two piles 30 amounts to 50 μm or to another value of a range between 20 μm and 200 μm. In general, the size of a pile 30 is typically four times or two times larger than a distance between two trenches 14.

According to a further embodiment an epitaxial layer 32 may be formed on the layer 20. This epitaxial layer 32 grows on the closed main surface 10a′ and enables to adjust the thickness of the layer 20 more precisely. This is illustrated by FIG. 2c which shows the layer 20 comprising the epitaxial layer 32 after separating same from the substrate 10. This epitaxial layer 32 which comprises the layer material of the layer 20 forms a new first main surface 10a″ in parallel to the closed main surface 10a′.

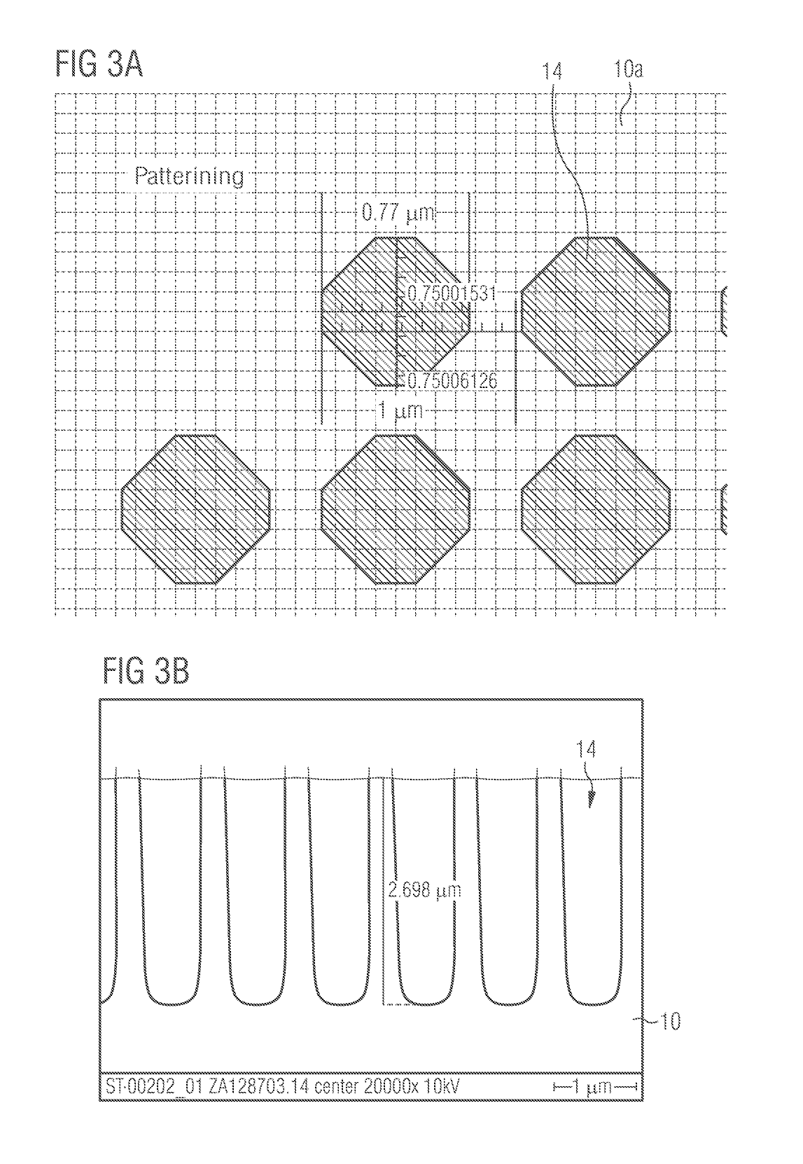

FIG. 3a shows a top view of a layout of the main surface 10a. The layout shows the plurality of trenches 14 to be provided and especially the arrangement of same. From the layout the even distribution of the trenches 14 can easily be seen. In this embodiment the trenches 14, which may have a round or octagonal shape, have the size of 0.77 μm, wherein the pitch amounts to 1 μm. In general, a ratio between the pitch and a diameter of the trench 14 is preferably 4:3 or at least 2:1 dependent on the thickness of the layer to be separated. This layout shown by FIG. 3a is patterned to the substrate 10 such that the trenches may be provided according to the layout, as illustrated by FIG. 3b.

FIG. 3b shows an x-ray of the substrate 10 after deep trench etching. Here, the trenches 14 extend up to a depth of 2.7 μm or in general up to a depth which is preferably four times or at least three times larger when compared to diameter of the respective trench 14. The background thereof is that the vertical arrangement of the cavities to be formed during the annealing process depends on the depth of the respective trenches 14.

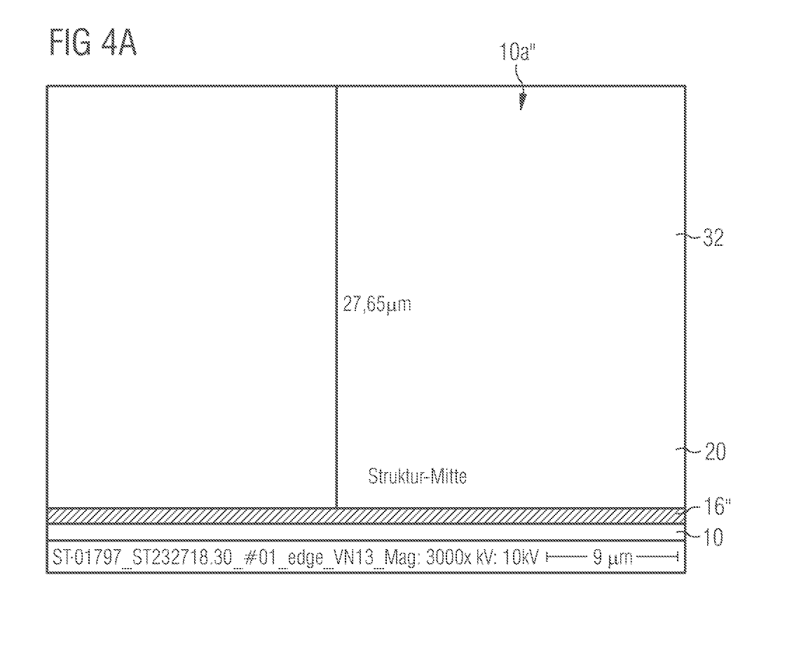

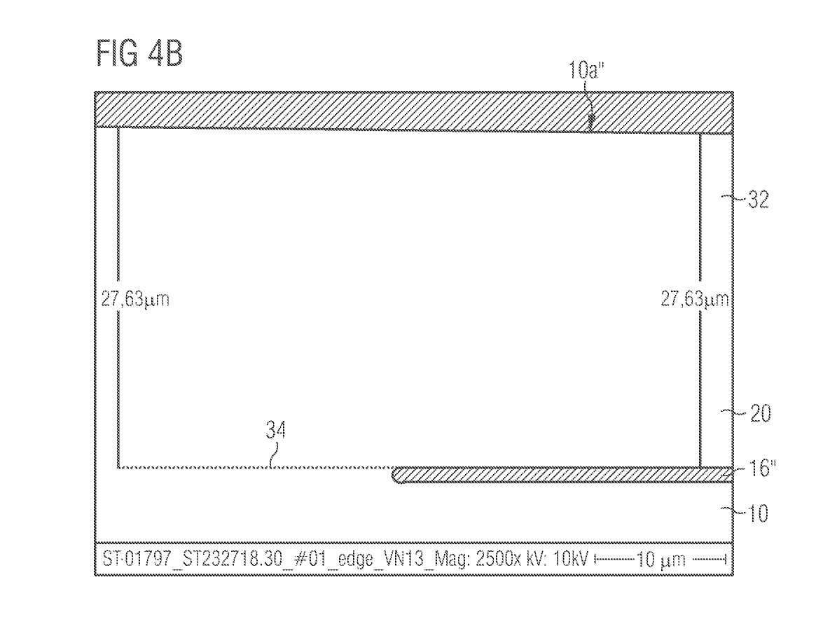

FIG. 4a shows an x-ray of the substrate 10 and the closed layer 20 comprising the epitaxial layer 32. Here, the cavity 16″ is arranged within a depth of approximately 27 μm, measured from the main surface 10a″ of the epitaxial layer 20. Consequently the thickness of the layer 20 amounts approximately to 27 μm after finishing the separation process.

FIG. 4b illustrates a further x-ray of the substrate 10 and the closed layer 20 (having the epitaxial layer 32) between which the cavity 16″ (separation area) is provided in a depth of approximately 27 μm (measured from the main surface 10a″ of the epitaxial layer 20). This x-ray of FIG. 4b shows an edge region 34 of the layer 20. The edge region 34 surrounds the portion of the layer 20 which should be separated. In this edge region 34 the layer 20 and the substrate 10 are still connected. Thus, for separating the layer 20 and the portion 20 of same, respectively, from the substrate 20 the edge region 34 is removed such that the portion 20 to be separated is diced along the edge region 34.

This dicing process will be exemplarily illustrated by FIG. 4c. FIG. 4c shows the substrate 10 and the layer 20 (portion 20) after singulating. Here, the separated portion 20 of the layer has a square shape, i.e., is lifted from the substrate 10 like a dice. This is done by a two-stage process. First the singular cavity is provided between the portion 20 and the substrate 10 according to the above described method, wherein no trenches are provided within the edge region 34 (cf. FIG. 4b, i.e., that the portion 20 is still connected to the substrate 10 after performing the annealing process). The second stage is the separation of the portion 20 which may be performed by a further etching process. During this etching process, additional trenches are provided along the edge region 34 in order to carve out the portion 20 from the substrate 10. Vice versa, that means that the shape of the diced portion 20 is defined by the additional trenches. Note that the edge region 34 may, alternatively, be removed by using another separation technology, e.g., by wafer-sawing.

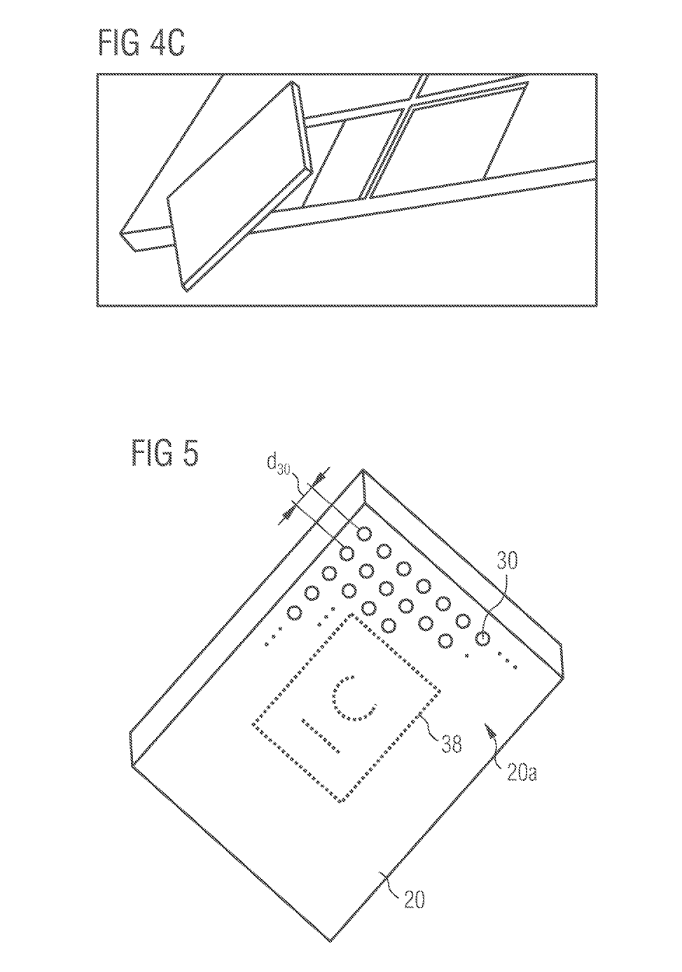

FIG. 5 shows a separated layer 20 which is separated according to the above described method and diced. The layer 20 comprises, for example, SiC. Here, the second main surface 20a facing the first main surface 10a is shown. The first main surface 10a comprises a chip area wherein an integrated circuit 38 is formed on same.

Furthermore, the layer 20 comprises the piles 30 which have been provided in order to stabilize the structure of the thin layer 20. The dimensions of the piles 30 which typically have a square shape are 0.5 μm×0.5 μm, or in general are smaller than 15 μm×15 μm. The piles 30 distributed over the entire surface 20a are typically spaced from each other by a distance d₃₀ of approximately 50 μm or in general more than 30 μm.

Although some aspects have been described in the context of an apparatus, it is clear the aspects also represent a description of the corresponding method, wherein a block or device corresponds to a method step or a feature of a method step. Analogously, aspects described in the context of a method step also represent a description of a corresponding block or item or feature of a corresponding apparatus.

The above described embodiments are merely illustrative for the principles of the present invention. It is understood that modifications and variations of the arrangements and the details described herein will be apparent to others skilled in the art. Therefore, it is the intent to be limited only the scope of the appending patent claims and not by the specific details presented by way of description and explanation of the embodiments herein.

What is claimed is:

1. A method for separating a layer from a substrate, comprising:
providing a plurality of trenches extending from a first main surface of the substrate into the substrate;
performing a heat treatment of the substrate such that edges of the trenches grow together at the first main surface to form a closed layer at the first main surface, wherein lower portions of the trenches form one or more cavities within the substrate; and
separating the closed layer from the substrate along the one or more cavities.

2. The method according to claim 1, wherein the step of providing the plurality of trenches is performed such that the trenches lie adjacent to each other.

3. The method according to claim 1, wherein the step of providing the plurality of trenches is performed such that the trenches are laterally distributed over an entire area of the substrate or over a portion of the substrate comprising the layer.

4. The method according to claim 1, wherein the step of providing the plurality of trenches is performed such that the trenches are evenly distributed over an entire area of the substrate or over a portion of the substrate comprising the layer.

5. The method according to claim 1, wherein a diameter of each trench is larger than 350 nm and wherein an average pitch between two adjacent trenches is smaller than 10 μm.

6. The method according to claim 1, wherein the step of providing the plurality of trenches is performed such that the trenches cover at least 20% of an entire area of the first main surface or of a portion of the substrate comprising the layer.

7. The method according to claim 1, wherein the step of providing the plurality of trenches is performed by deep trench etching.

8. The method according to claim 1, wherein the step of performing the heat treatment is performed as long as the one or more cavities form an entire cavity extending in parallel to the first main surface of the substrate.

9. The method according to claim 1, wherein the step of performing the heat treatment is performed as long as the one or more cavities form a separation region extending in parallel to the first main surface over an entire area of a portion of the layer to be separated.

10. The method according to claim 9, wherein the portion of the layer is surrounded by an edge region, and wherein the step of separating the closed layer comprises a sub-step of removing the edge region.

11. The method according to claim 1, wherein the one or more cavities are arranged in a depth of the substrate which is smaller than 10% of a thickness of the substrate.

12. The method according to claim 1, comprising a step of providing an epitaxial layer on the closed layer to adjust a thickness of the layer after performing the heat treatment.

13. The method according to claim 1, wherein the steps of the method are repeated such that a plurality of closed layers is separated from the substrate.

14. The method according to claim 1, wherein the heat treatment is performed at a temperature which depends on a flow temperature of a material of the substrate.

15. The method according to claim 1, wherein the substrate to be separated comprises silicon and/or carbon.

16. The method according to claim 1, wherein the heat treatment is performed at a temperature which is above 1000° C.

17. The method according to claim 1, wherein the method comprises a step of providing hydrogen ambient surrounding the substrate before performing the heat treatment.

18. The method according to claim 1, wherein the step of separating the substrate is performed by using handling support means which are configured to reduce the mechanical stress to the closed layer.

19. The method according to claim 18, wherein the handling support means comprise a further substrate attached to the closed layer or a wafer carrier for the closed layer.

20. The method according to claim 1, further comprising a step of providing piles before providing the plurality of trenches.

21. The method according to claim 1, further comprising a step of providing a plurality of dicing trenches surrounding a chip area formed on the layer into the substrate before separating the closed layer from the substrate, and
wherein the step of separating the closed layer from the substrate is performed such that the layer having the shape of a chip is separated from the substrate along the dicing trenches.

22. A method for separating layers from a substrate comprising silicon and/or carbon, comprising:
providing a plurality of trenches extending from a first main surface of the substrate into the substrate, wherein the trenches are laterally and evenly distributed over an entire area of the substrate, wherein a diameter of each trench is larger than 350 nm and wherein an average pitch between two adjacent trenches is smaller than 10 μm;
providing hydrogen ambient surrounding the substrate;
performing a heat treatment of the substrate at a temperature above 1000° C. such that edges of the trenches grow together at the first main surface to form a closed layer at the first main surface, wherein lower portions of the trenches form one or more cavities within the substrate; and
separating the closed layer from the substrate along the one or more cavities,
wherein the step of performing the heat treatment is performed as long as the one or more cavities form an entire cavity extending in parallel to the first main surface of the substrate,
wherein the steps of the method are repeated such that a plurality of closed layers are separated from the substrate.

23. A chip, comprising:
a layer being thinner than 100 μm;
a plurality of piles integrated into the layer; and
a chip area formed on the layer and comprising an integrated circuit.

24. The chip according to claim 23, wherein the piles are laterally distributed over the layer such that an average pitch is smaller than 100 μm.

25. The chip according to claim 23, wherein a diameter of the piles is smaller than 10 μm.
